(19) United States
(12) Patent Application Publication
(10) Pub. No.: US 2026/0075752 A1
(43) Pub. Date: Mar. 12, 2026

(54) IMMERSION HEAT DISSIPATION STRUCTURE

(71) Applicant: JWS TECHNOLOGY CO., LTD., New Taipei City (TW)

(72) Inventors: Pang-Hung LIAO, New Taipei City (TW); Chih-Wei CHEN, New Taipei City (TW); Chia-Yi CHUANG, New Taipei City (TW)

(21) Appl. No.: 18/827,641

(22) Filed: Sep. 6, 2024

(51) Int. Cl. H05K 7/20

(52) U.S. Cl. CPC H05K 7/20236

(57) ABSTRACT

An immersion heat dissipation structure includes: a heat dissipating fin set, having a plurality of heat dissipating fins parallelly disposed and a plurality of spaced flow channels arranged between each of the two adjacent heat dissipating fins, each heat dissipating fin having a notch inwardly formed from an outer circumference thereof, a recessed passageway being defined by the plurality of the notches, and the recessed passageway and the plurality of the spaced flow channels communicating with each other; and a sealed housing, covering an outer side of the plurality of the heat dissipating fins and having has at least one liquid input port arranged corresponding to the recessed passageway and at least one liquid output port arranged corresponding to the plurality of the spaced flow channels. Accordingly, a desirable heat dissipating efficiency is provided.

### BACKGROUND OF THE DISCLOSURE

### Technical Field

The present disclosure relates to a heat dissipation structure, especially to an immersion heat dissipation structure.

### Description of Related Art

An immersion cooling technology is provided to a heat dissipation device used in a server. Thermal energy generated by electronic components may be transferred to a dielectric liquid which is not electrically conductive by directly immersing the server in the dielectric liquid. The dielectric liquid having a raised temperature flows back to continuously absorb the thermal energy with a circular cooling manner.

A related-art immersion heat dissipation structure makes the dielectric liquid flow through thinned heat dissipating fins to increase a heat dissipating area. However, a viscosity of the dielectric liquid is greater than that of the air. If a space between the thinned heat dissipating fins is too narrow, a flow resistance of the dielectric liquid is increased, and the dissipating performance is decreased; on the other hand, for reducing the flow resistance of the dielectric liquid to make the space between the heat dissipating fins be increased, the amount of the heat dissipating fins defined in the same area is decreased, and the heating resistance value is increased.

Accordingly, the applicant of the present disclosure has devoted himself for improving the mentioned shortages.

### SUMMARY OF THE INVENTION

The present disclosure provides an immersion heat dissipation structure, in which a plurality of heat dissipating fins respectively has a notch inwardly formed from an outer circumference thereof, and a recessed passageway is surrounded by the plurality of the notches, thus a desirable heat dissipating efficiency is achieved by the immersion heat dissipation structure of the present disclosure.

Accordingly, the present disclosure provides an immersion heat dissipation structure, which includes: a heat dissipating fin set, having a plurality of heat dissipating fins parallelly disposed and a plurality of spaced flow channels arranged between each of the two adjacent heat dissipating fins, wherein the plurality of the heat dissipating fins respectively have a notch inwardly formed from an outer circumference thereof, a recessed passageway is surrounded by the plurality of the notches, and the recessed passageway and the plurality of the spaced flow channels communicate with each other; and a sealed housing, covering an outer side of the plurality of the heat dissipating fins and having at least one liquid input port arranged corresponding to the recessed passageway and at least one liquid output port arranged corresponding to the plurality of the spaced flow channels.

Based on what has been disclosed above, the recessed passageway is configured by the plurality of the notches inwardly formed from the outer circumference of the heat dissipating fins, each of the heat dissipating fins is formed on a substrate with a manner of a milling or a cutting process, and the notches are formed on the heat dissipating fins with a manner of a milling or a cutting process. As such, a space between the adjacent spaced flow channels is smaller, the amount of the heat dissipating fin is increased, and the heat dissipating fin is disposed on the substrate with the milling or the cutting manner to make the heat dissipating fin and the substrate be configured in one piece, advantages of not having the resistance caused by the soldering and providing the direct heat transferring are provided. A soldering heat set is eliminated comparing to a manner of soldering or pushing fins. Accordingly, the immersion heat dissipation structure has advantages of increasing the heat dissipating cross sectional area, lowering the thermal resistance value, simplifying the producing steps and saving the production cost.

### BRIEF DESCRIPTION OF THE DRAWINGS

FIG. 1 is a perspective exploded view showing the immersion heat dissipation structure according to the first embodiment of the present disclosure;

FIG. 2 is a perspective enlarged view showing the selected area of FIG. 1 according to the first embodiment of the present disclosure;

FIG. 3 is a perspective view showing the assembly of the immersion heat dissipation structure according to the first embodiment of the present disclosure;

FIG. 4 is a cross sectional view showing the assembly of the immersion heat dissipation structure according to the first embodiment of the present disclosure;

FIG. 5 is another cross sectional view showing the assembly of the immersion heat dissipation structure according to the first embodiment of the present disclosure;

FIG. 6 is a schematic view showing an operating status of the immersion heat dissipation structure according to the present disclosure;

FIG. 7 is a perspective view showing the assembly of the immersion heat dissipation structure according to the second embodiment of the present disclosure;

FIG. 8 is a cross sectional view showing the assembly of the immersion heat dissipation structure according to the second embodiment of the present disclosure;

FIG. 9 is a perspective view showing the assembly of the immersion heat dissipation structure according to the third embodiment of the present disclosure;

FIG. 10 is a cross sectional view showing the assembly of the immersion heat dissipation structure according to the third embodiment of the present disclosure;

FIG. 11 is a perspective view showing the assembly of the immersion heat dissipation structure according to the fourth embodiment of the present disclosure;

FIG. 12 is a cross sectional view showing the assembly of the immersion heat dissipation structure according to the fourth embodiment of the present disclosure; and

FIG. 13 is a perspective view showing the assembly of the immersion heat dissipation structure according to the fifth embodiment of the present disclosure.

### DETAILED DESCRIPTION

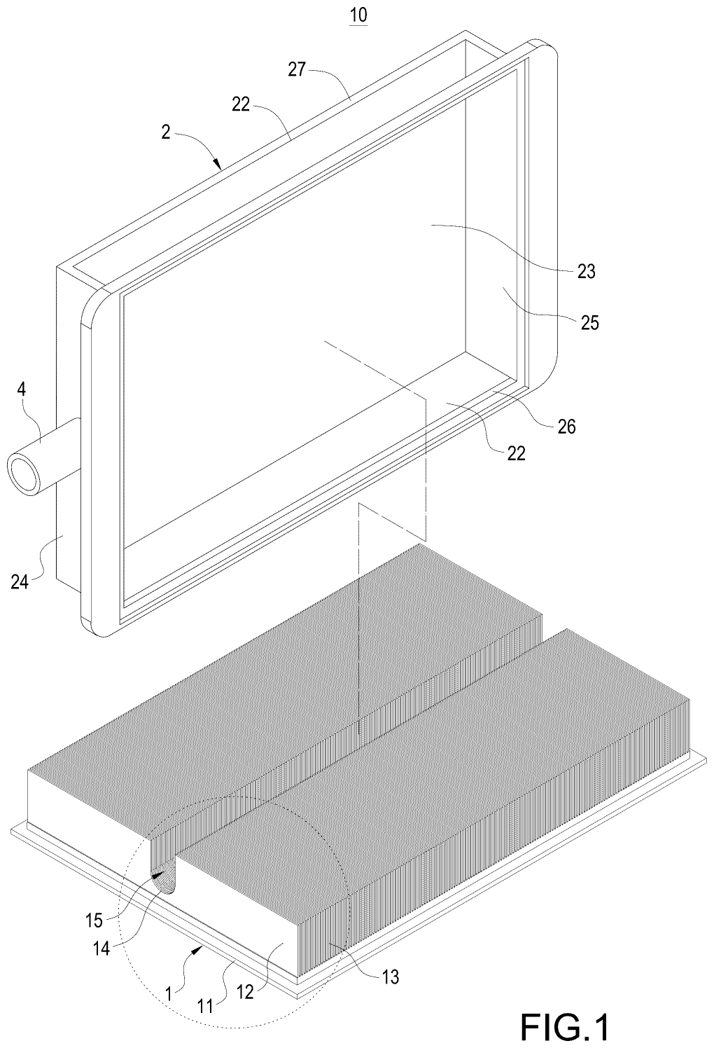

Please refer from FIG. 1 to FIG. 6, the present disclosure provides an immersion heat dissipation structure. According the first embodiment of the present disclosure, the immersion heat dissipation structure 10 mainly includes a heat dissipating fin set 1 and a sealed housing 2.

As shown from FIG. 1 to FIG. 5, the heat dissipating fin set 1 has a substrate 11, a plurality of heat dissipating fins 12 parallelly disposed on the substrate 11 and a plurality of spaced flow channels 13 arranged between each of the two adjacent heat dissipating fins 12. The plurality of the heat dissipating fins 12 respectively have a notch 14 inwardly formed from an outer circumference thereof, and a recessed passageway 15 is defined by being surrounded by the plurality of the notches 14. The recessed passageway 15 and the plurality of the spaced flow channels communicate with each other.

In some embodiments, the plurality of the heat dissipating fins 12 are formed on the substrate 11 with a manner of a milling or a cutting process. The notch 14 is formed on each of the heat dissipating fins 12 with a manner of a milling or a cutting process. The milling or the cutting process disclosed in this embodiment of the present disclosure is served as an example for illustrations, but the forming manner of the heat dissipating fin 12 is not intended to be limiting. The plurality of the heat dissipating fins 12 may be formed on the substrate 11 with any processing manner, for example soldering or punching fins. When the milling or the cutting manner are adopted, the substrate 11 contacting a heat source and the heat dissipating fins 12 are formed in one piece to make heat be directly transferred to the heat dissipating fins 12. A soldering heat set is eliminated comparing to the manner of soldering or pushing fins. The notch 14 is formed on each of the heat dissipating fins 12 with any desired processing manner, and the recessed passageway 15 is disposed at a central portion of the plurality of the heat dissipating fins 12, but here is not intended to be limiting. The recessed passageway 15 may be disposed at any location, for example towards a left side or a right side of the plurality of the the heat dissipating fins 12 according to actual needs.

In some embodiments, the heat dissipating fin set 1 has a long side L1 and a short side L2. The arranged direction of the recessed passageway 15 is parallel to the long side L1, in other words, the long side L1 of the heat dissipating fin set 1 is a sum of a thickness of each of the heat dissipating fins 12 and a spaced dimension of each of the spaced flow channels 13, and the short side L2 of the heat dissipating fin set 1 is a length of single heat dissipating fin 12.

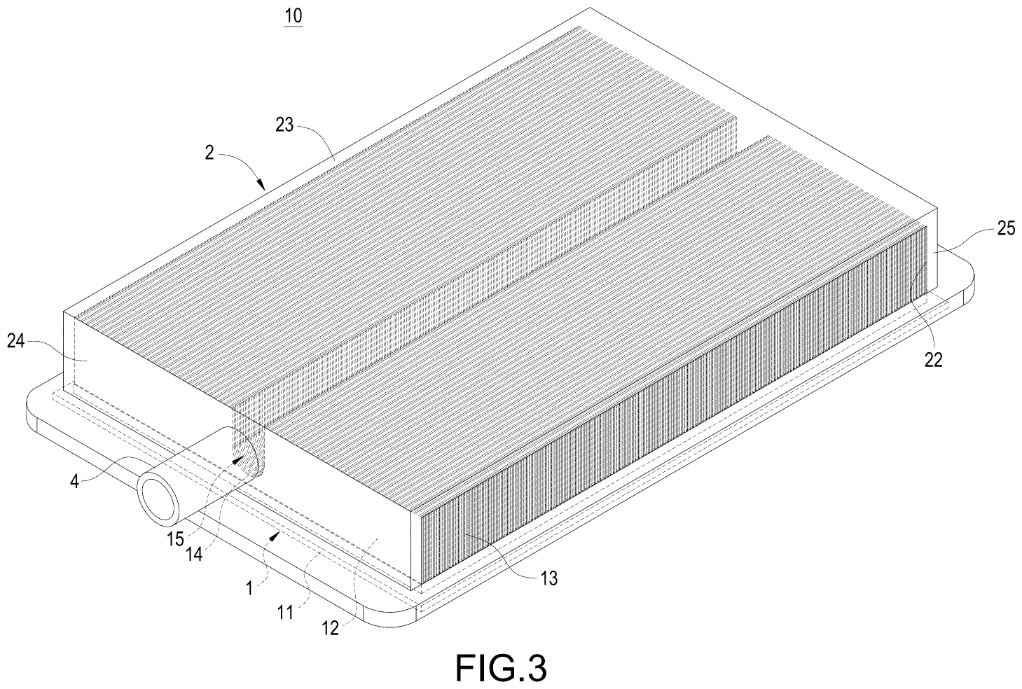

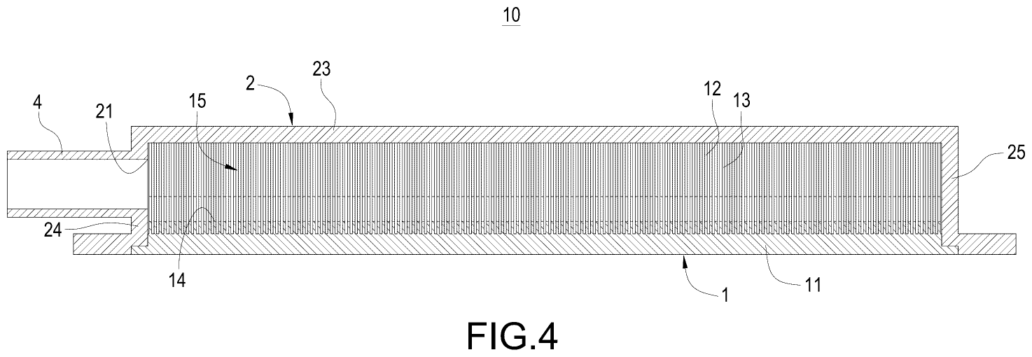

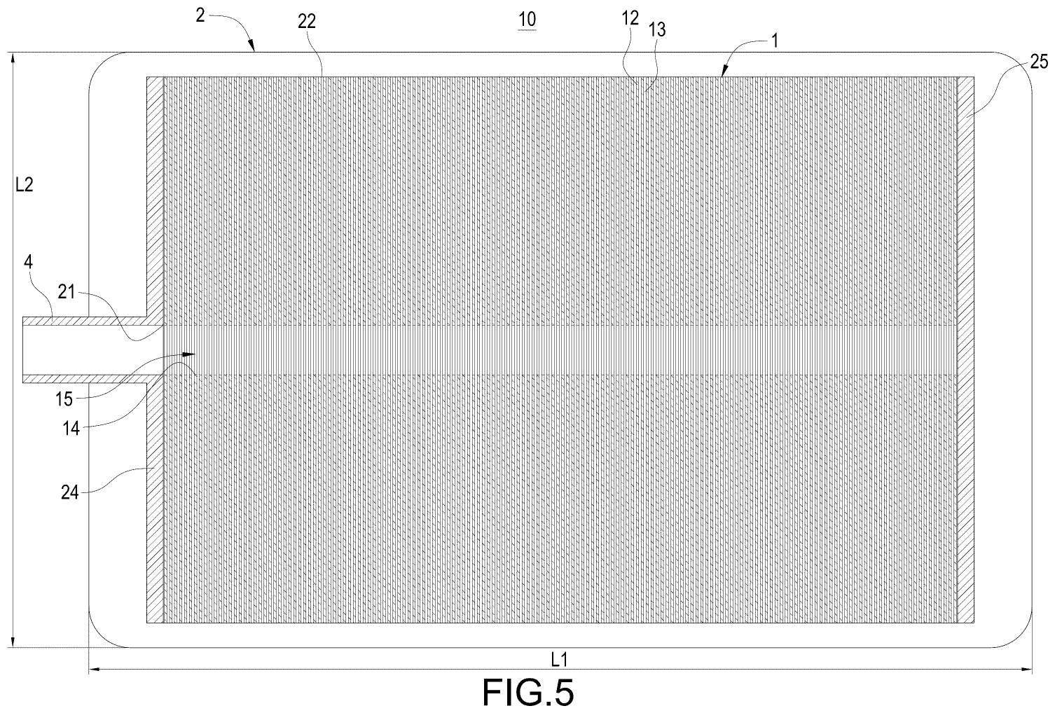

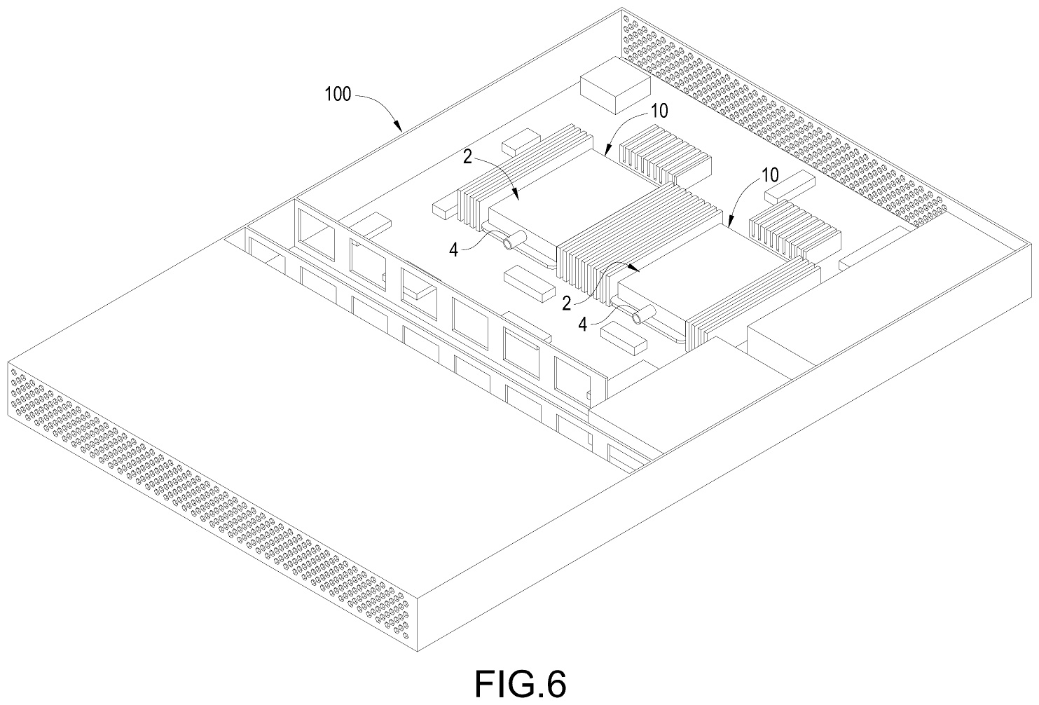

As shown in FIG. 1, FIG. 3, FIG. 4, FIG. 5 and FIG. 6, the sealed housing 2 covers an outer side of the plurality of the heat dissipating fins 12. The sealed housing 2 has one or a plurality of liquid input ports 21 arranged corresponding to the recessed passageway 15 and one or a plurality of liquid output ports 22 arranged corresponding to the plurality of the spaced flow channels 13.

Details are provided as follows. The sealed housing 2 is connected to the substrate 11 with a soldering or a locking manner to cover on top of the substrate 11. The sealed housing 2 has a top plate 23 and a front plate 24, a rear plate 25, a left plate 26 and a right plate 27 surrounding an outer periphery of the top plate 23.

In some embodiments, the amount of the liquid input port 21 is one, the amount of the liquid output port 22 is two. Each of the notches 14 is concavely formed on a top edge of each of the heat dissipating fins 12. The front plate 24 has the liquid input port 21 and a liquid input pipe 4 extended from the front plate 24 and surrounding an outer circumference of the liquid input port 21. One of the liquid output ports 22 is formed on the left plate 26 corresponding to and communicating with one end of the plurality of the spaced flow channels 13. The other liquid output port 22 is formed on the right plate 27 corresponding to and communicating with another end of the plurality of the spaced flow channels 13.

Please refer from FIG. 1 to FIG. 6, which disclosure an operating status of the immersion heat dissipation structure 10 according to the present disclosure. The immersion heat dissipation structure 10 is disposed in a server 100. The server 100 is disposed in a cooling tank (not shown in figures). The server 100 is immersed in a dielectric liquid which is not electrically conductive and disposed in the cooling tank, thus the heat dissipation to a heat source (not shown in figures) of the server 100 is conducted via the immersion heat dissipation structure 10.

Details are provided as follows. The substrate 11 is thermally attached on top of the heat source, the dielectric liquid is pressurized by a pump (not shown in figures) to make the dielectric liquid flow into the liquid input port 21 via the liquid input pipe 4, thus a cross sectional area of the recessed passageway 15 is greatly larger than a cross sectional area of the spaced flow channel 13, the dielectric liquid is rapidly filled up in the recessed passageway 15, the dielectric liquid evenly flows towards each of the spaced flow channels 13 through the recessed passageway 15, and then the dielectric liquid flows through each of the spaced flow channels 13 to absorb the thermal energy of the heat source and be discharged out of the sealed housing 2 via the liquid output ports 22. As such, a desirable heat dissipating efficiency is achieved by the immersion heat dissipation structure 10 of the present disclosure.

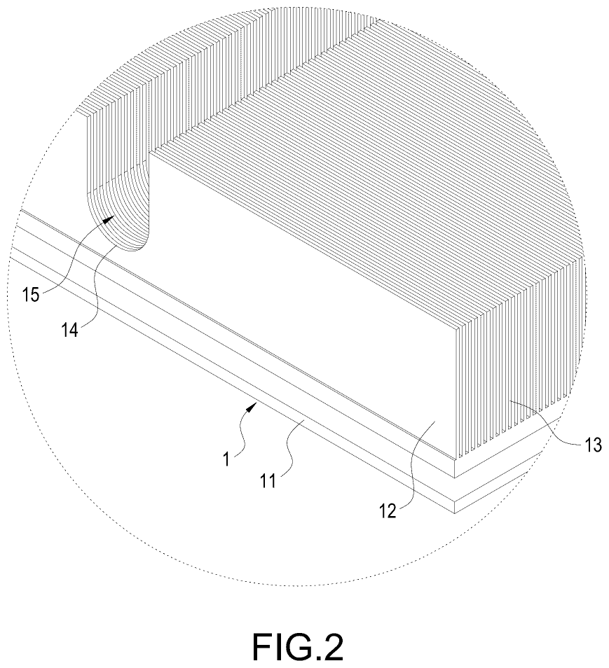

Please refer to FIG. 2, the arranged direction of the recessed passageway 15 is parallel to the long side L1 of the heat dissipating fin set 1, thus the dielectric liquid flows along the recessed passageway 15 and then flows out from two ends of each of the spaced flow channels 13, in other words, the dielectric liquid flows along a path of the short side L2 of the heat dissipating fin set 1. Accordingly, comparing to the dielectric liquid flowing along a path of the long side L1 of the heat dissipating fin set 1, the dielectric liquid flowing along the path of the short side L2 of the heat dissipating fin set 1 provided by the present disclosure has a shorter flow path and a greater flow cross sectional area, thus the dielectric liquid rapidly and smoothly flows towards each of the spaced flow channels 13 through the recessed passageway 15, and a flow resistance of the dielectric liquid is reduced to increase the heat dissipating efficiency, and the heat dissipating efficiency of the immersion heat dissipation structure 10 is further enhanced.

The recessed passageway 15 is configured by the plurality of the notches 14 inwardly formed from the outer circumference of the heat dissipating fins 12. In some embodiments, the plurality of the heat dissipating fins 12 are formed on the substrate 11 with a manner of the milling or the cutting process. The notch 14 is formed on each of the heat dissipating fins 12 with a manner of the milling or the cutting process. As such, a space between the adjacent spaced flow channels 13 is smaller, the amount of the heat dissipating fin 12 is increased, and the heat dissipating fin 12 is disposed on the substrate 11 with the milling or the cutting manner to make the heat dissipating fin 12 and the substrate 11 be configured in one piece, advantages of not having the resistance caused by the soldering and providing the direct heat transferring are provided. A soldering heat set is eliminated comparing to the manner of soldering or pushing fins. Accordingly, the immersion heat dissipation structure 10 has advantages of increasing the heat dissipating cross sectional area, lowering the thermal resistance value, simplifying the producing steps and saving the production cost.

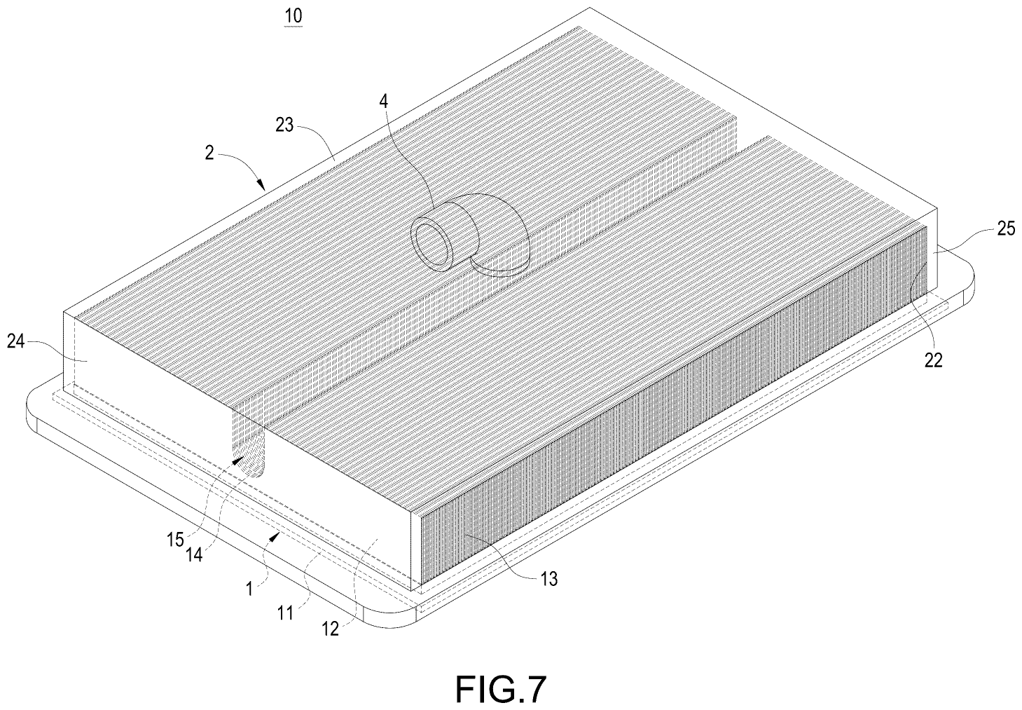

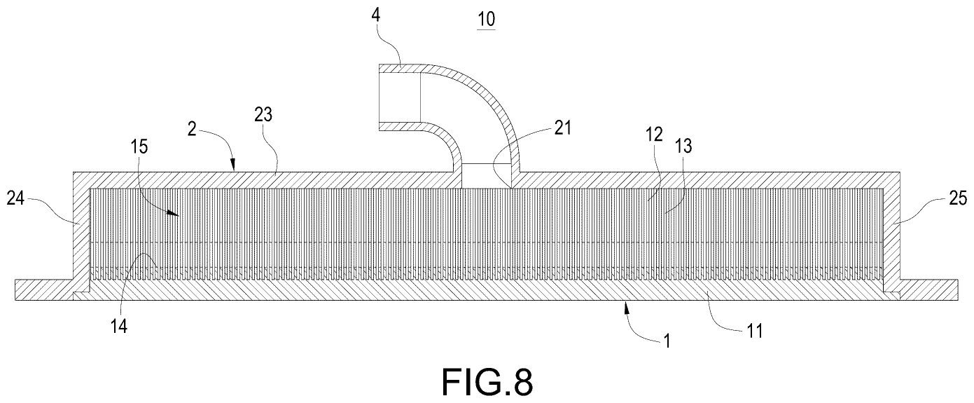

Please refer to FIG. 7 and FIG. 8, which disclose the second embodiment of the immersion heat dissipation structure 10 of the present disclosure. The second embodiment disclosed in FIG. 7 and FIG. 8 is substantially the same as the first embodiment disclosed from FIG. 1 to FIG. 6. The difference between the second embodiment disclosed in FIG. 7 and FIG. 8 and the first embodiment disclosed from FIG. 1 to FIG. 6 is the disposing location of the liquid input port 21 is different.

Details are provided as follows. In some embodiments, the amount of the liquid input port 21 is one. The amount of the liquid output port 22 is two. Each of the notches 14 is concavely formed on the top edge of each of the heat dissipating fins 12. The top plate 23 has the liquid input port 21 and the liquid input pipe 4 extended from the top plate 23 and surrounding an outer circumference of the liquid input port 21. One of the liquid output ports 22 is formed on the left plate 26 corresponding to and communicating with one end of the plurality of the spaced flow channels 13. The other liquid output port 22 is formed on the right plate 27 corresponding to and communicating with another end of the plurality of the spaced flow channels 13.

According to the embodiment disclosed from FIG. 1 to FIG. 6, the liquid is inputted from the front side of the substrate 11, the heat source is mostly disposed at a middle portion of the substrate 11, thus the dielectric liquid is firstly heated at the front end and then flows through the heat source. In this embodiment, the liquid is inputted from a top end of the substrate 11, the dielectric liquid is guided to a location close to the heat source and then be inputted, thus the heat source is cooled in a faster manner, and the heat dissipating efficiency of the immersion heat dissipation structure 10 is further enhanced.

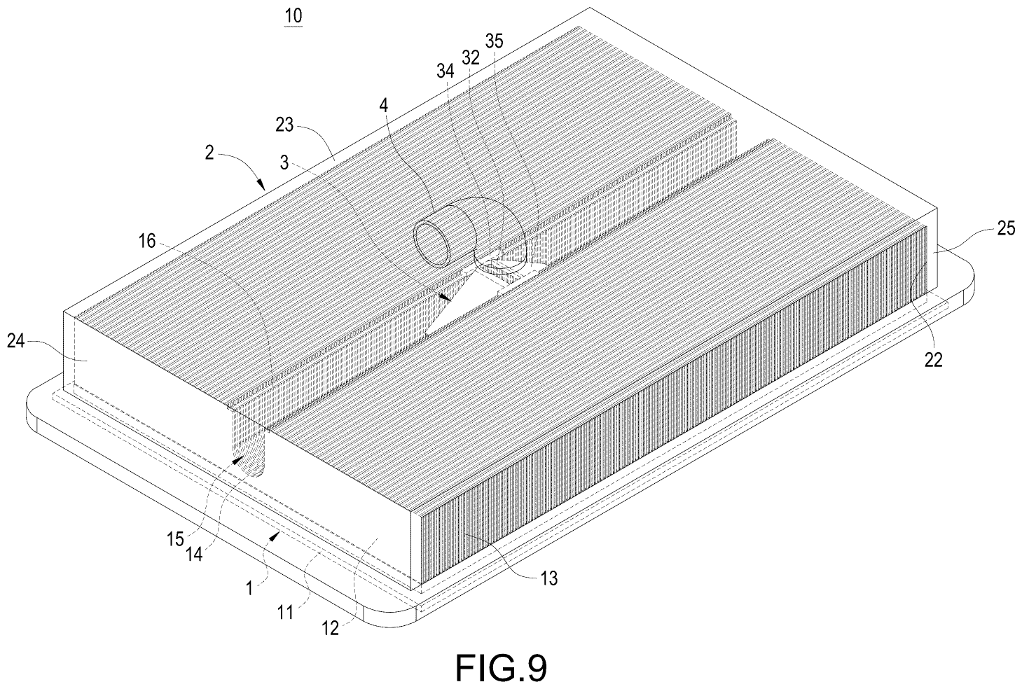

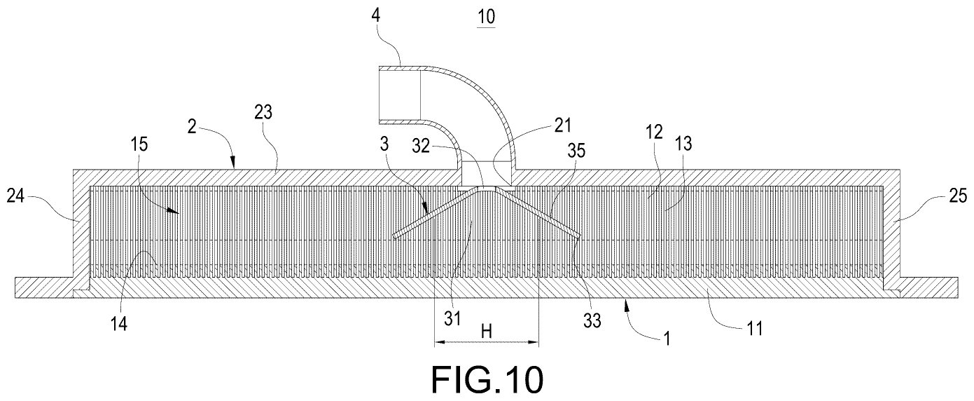

Please refer to FIG. 9 and FIG. 10, which disclose the third embodiment of the immersion heat dissipation structure 10 of the present disclosure. The third embodiment disclosed in FIG. 9 and FIG. 10 is substantially the same as the second embodiment disclosed in FIG. 7 and FIG. 8. The differences between the third embodiment disclosed in FIG. 9 and FIG. 10 and the second embodiment disclosed in FIG. 7 and FIG. 8 is the immersion heat dissipation structure 10 further includes a flow guiding member 3.

The immersion heat dissipation structure 10 of the present disclosure further includes one or a plurality of flow guiding members 3. The flow guiding member 3 is disposed in the recessed passageway 15 and arranged corresponding to the liquid input port 21. The flow guiding member 3 has a conical passageway 31 and a first opening 32 and a second opening 33 disposed at two ends of the conical passageway 31. The first opening 32 is arranged corresponding to the liquid input port 21. A caliber H of the conical passageway 31 is gradually increased from the first opening 32 towards the second opening 33.

Details are provided as follows. Two latching grooves 16 are inwardly formed from the outer circumference of the plurality of the heat dissipating fins 12 and disposed at two sides of the recessed passageway 15. The flow guiding member 3 has two strip-shaped latching blocks 34 and two inclined plates 35 crossly disposed (connected) between the two strip-shaped latching blocks 34. The two strip-shaped latching blocks 34 are latched in the two latching grooves 16. The first opening 32 is defined by being surrounded by one end of the two inclined plates 35, the second opening 33 is defined by being surrounded by another end of the two inclined plates 35, and the conical passageway 31 is defined by the inner side of the two inclined plates 35.

Accordingly, an impact force of the dielectric liquid flowing into the recessed passageway 15 is reduced via the conical passageway 31 of the flow guiding member 3. Especially, a problem of greatly lowering an instant flow speed due to the dielectric liquid being inputted from the top end to impact a wall surface at a bottom side of the recessed passageway 15 is solved, and a situation of deceleration happened when the dielectric liquid flowing through the liquid input port 21, the recessed passageway 15 and the spaced flow channel 13 is avoided.

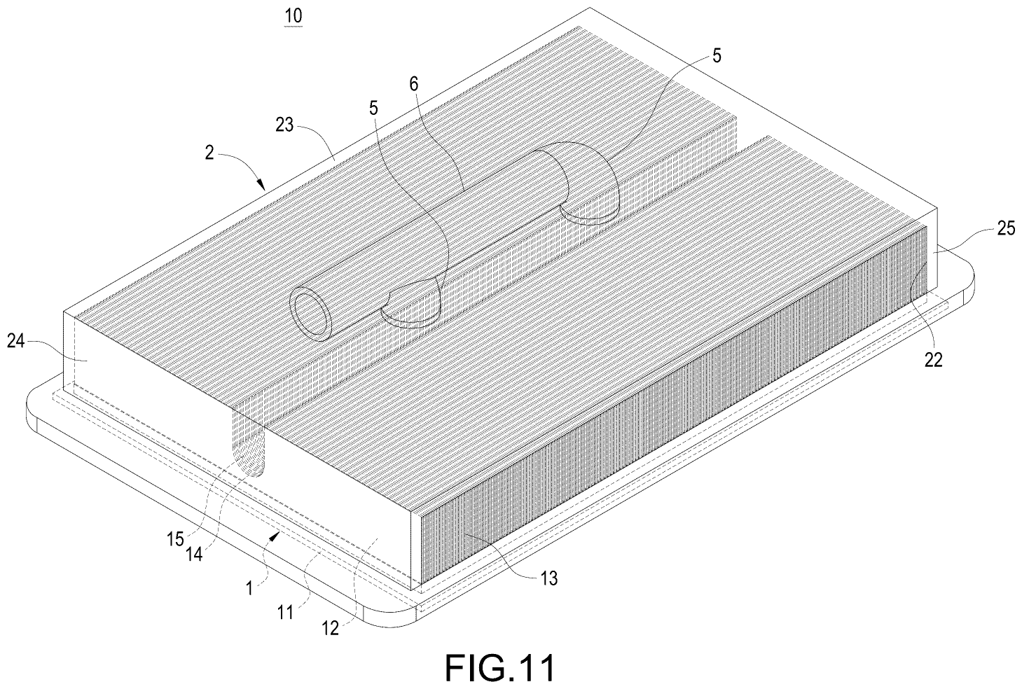

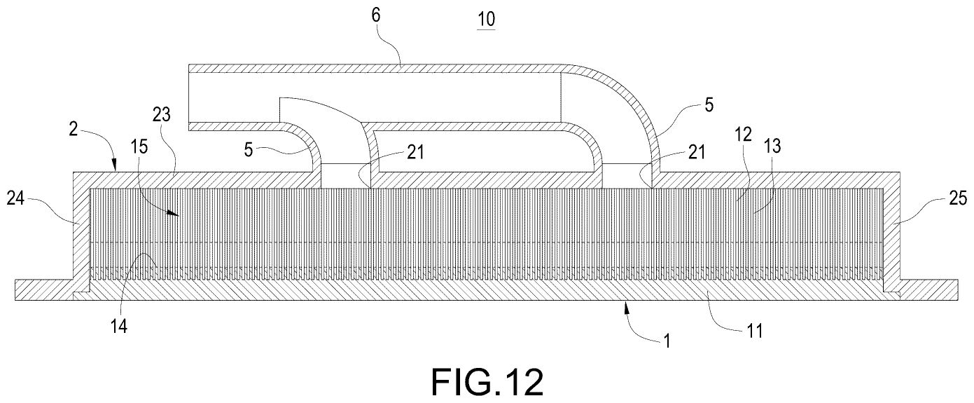

Please refer to FIG. 11 and FIG. 12, which disclose the fourth embodiment of the immersion heat dissipation structure 10 of the present disclosure. The fourth embodiment disclosed in FIG. 11 and FIG. 12 is substantially the same as the second embodiment disclosed in FIG. 7 and FIG. 8. The differences between the fourth embodiment disclosed in FIG. 11 and FIG. 12 and the second embodiment disclosed in FIG. 7 and FIG. 8 is the amount of the liquid input port 12 is multiple.

Details are provided as follows. According to this embodiment, the amount of the liquid input port 21 is multiple. The amount of the liquid output port 22 is two. Each of the notches 14 is concavely formed on the top edge of each of the heat dissipating fins 12. The top plate 23 has the plurality of the liquid input ports 21, a plurality of shunt pipes 5 extended from the top plate 23 and surrounding an outer circumference of each of the liquid input ports 21 and a main pipe 6 communicating with the plurality of the shunt pipes 5. One of the liquid output ports 22 is formed on the left plate 26 corresponding to and communicating with one end of the plurality of the spaced flow channels 13. The other liquid output port 22 is formed on the right plate 27 corresponding to and communicating with another end of the plurality of the spaced flow channels 13.

Accordingly, if there are a plurality of heat sources, each of the liquid input ports 21 is respectively arranged corresponding to each of the heat sources, and each of the liquid input ports 21 directly guides the dielectric liquid to be inputted close to each of the heat sources, thus the immersion heat dissipation structure 10 is provided with an effect of dissipating heat generated by the plurality of the heat sources.

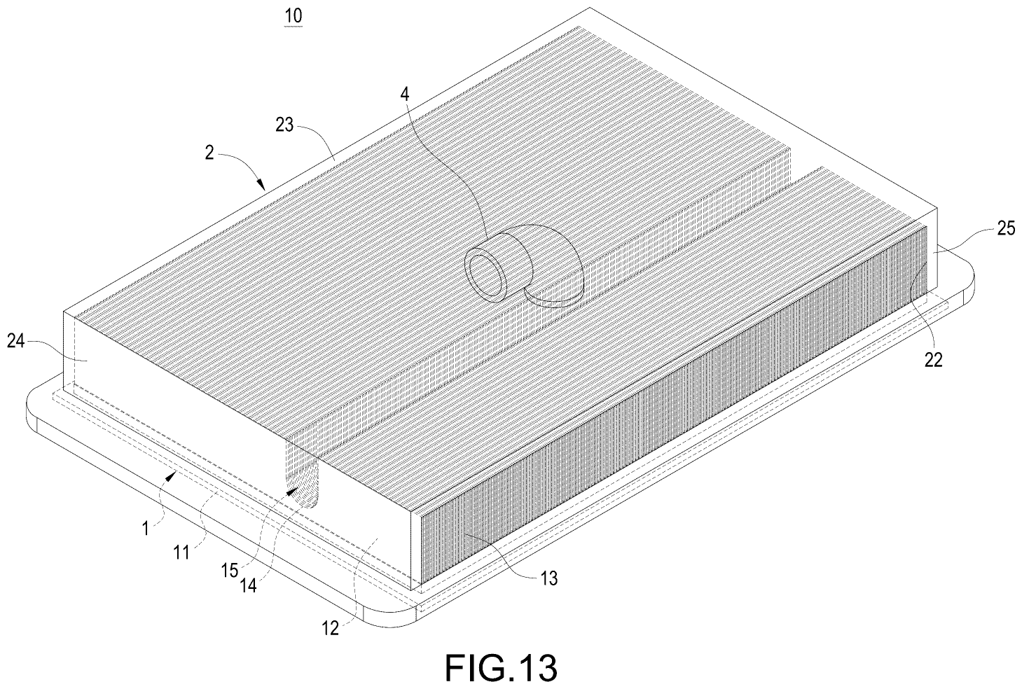

Please refer to FIG. 13, which disclose the fifth embodiment of the immersion heat dissipation structure 10 of the present disclosure. The fifth embodiment disclosed in FIG. 13 is substantially the same as the second embodiment disclosed in FIG. 7 and FIG. 8. The differences between the fifth embodiment disclosed in FIG. 13 and the second embodiment disclosed in FIG. 7 and FIG. 8 is the recessed passageway 15 is located towards the right side of the plurality of the heat dissipating fins 12, but here is not intended to be limiting. The recessed passageway 15 may be disposed at any desired location, for example at the middle or towards the left side, of the plurality of the heat dissipating fins 2 according to actual needs.

Details are provided as follows. According to this embodiment, the recessed passageway 15 is disposed towards the right side of the plurality of the heat dissipating fins 12, thus a path defied from the recessed passageway 15 to the right side of the heat dissipating fin 2 is shorter to make the flow resistance be lower. A path defined from the recessed passageway 15 to the left side of the heat dissipating fin 2 is longer to make the flow resistance be greater. As such, the flow speed of the dielectric liquid is controlled by the length of the path defined from the recessed passageway 15 flowing to the location of the heat dissipating fin 12, thus a zone of the substrate 10 being attached with the heat source has a faster flow speed, and a zone of the substrate 10 not being attached with the heat source has a lower flow speed.

While this disclosure has been described by means of specific embodiments, numerous modifications and variations may be made thereto by those skilled in the art without departing from the scope and spirit of this disclosure set forth in the claims.

What is claimed is:

1. An immersion heat dissipation structure, comprising:
a heat dissipating fin set, comprising a plurality of heat dissipating fins parallelly disposed and a plurality of spaced flow channels arranged between any two of the heat dissipating fins adjacent to each other, wherein each of the heat dissipating fins comprises a notch inwardly defined from an outer circumference thereof, a recessed passageway is defined by a plurality of notches, and the recessed passageway and the plurality of the spaced flow channels communicate with each other; and
a sealed housing, covering an outer side of the plurality of the heat dissipating fins and comprising at least one liquid input port arranged corresponding to the recessed passageway and at least one liquid output port arranged corresponding to the plurality of the spaced flow channels.

2. The immersion heat dissipation structure according to claim 1, wherein the notch is defined on each of the heat dissipating fins by a milling or a cutting process.

3. The immersion heat dissipation structure according to claim 1, further comprising at least one flow guiding member accommodated in the recessed passageway and arranged corresponding to the liquid input port, the flow guiding member comprising a conical passageway and a first opening and a second opening defined on two ends of the conical passageway, wherein the first opening is arranged corresponding to the liquid input port, and a caliber of the conical passageway is gradually increased from the first opening towards the second opening.

4. The immersion heat dissipation structure according to claim 3, wherein two latching grooves are inwardly defined from the outer circumference of the plurality of the heat dissipating fins and located at two sides of the recessed passageway, the flow guiding member comprises two strip-shaped latching blocks and two inclined plates connected between the two strip-shaped latching blocks, the two strip-shaped latching blocks are latched in the two latching grooves, the first opening is defined by one ends of the two inclined plates, the second opening is defined by other ends of the two inclined plates, and the conical passageway is defined by inner sides of the two inclined plates.

5. The immersion heat dissipation structure according to claim 1, wherein the sealed housing comprises a top plate and a front plate, a rear plate, a left plate and a right plate surrounding an outer periphery of the top plate.

6. The immersion heat dissipation structure according to claim 5, wherein an amount of the liquid input port is one, an amount of the liquid output port is two, each of the notches is concavely defined on a top edge of each of the heat dissipating fins, the front plate comprises the liquid input port and a liquid input pipe extended therefrom and surrounding an outer circumference of the liquid input port, one of the liquid output ports is defined on the left plate corresponding to and communicating with one end of the plurality of the spaced flow channels, and another one of the liquid output ports is defined on the right plate corresponding to and communicating with another end of the plurality of the spaced flow channels.

7. The immersion heat dissipation structure according to claim 5, wherein an amount of the liquid input port is one, an amount of the liquid output port is two, each of the notches is concavely defined on a top edge of each of the heat dissipating fins, the top plate comprises the liquid input port and a liquid input pipe extended therefrom and surrounding an outer circumference of the liquid input port, one of the liquid output ports is defined on the left plate corresponding to and communicating with one end of the plurality of the spaced flow channels, and another one of the liquid output ports is defined on the right plate corresponding to and communicating with another end of the plurality of the spaced flow channels.

8. The immersion heat dissipation structure according to claim 5, wherein an amount of the liquid input port is multiple, an amount of the liquid output port is two, each of the notches is concavely defined on a top edge of each of the heat dissipating fins, the top plate comprises the plurality of the liquid input ports, a plurality of shunt pipes extended therefrom and surrounding an outer circumference of each of the liquid input ports, and a main pipe communicating with the plurality of the shunt pipes, one of the liquid output ports is defined on the left plate corresponding to and communicating with one end of the plurality of the spaced flow channels, and another one of the liquid output ports is defined on the right plate corresponding to and communicating with another end of the plurality of the spaced flow channels.

9. The immersion heat dissipation structure according to claim 1, wherein the recessed passageway is disposed at a middle portion of the plurality of the heat dissipating fins.

10. The immersion heat dissipation structure according to claim 1, wherein the heat dissipating fin set further comprises a substrate, the plurality of the heat dissipating fins are parallelly disposed on the substrate, and the sealed housing is connected to the substrate and covers the substrate.

11. The immersion heat dissipation structure according to claim 1, wherein the heat dissipating fin set comprises a long side and a short side, and an arranged direction of the recessed passageway is parallel to the long side.
